(19) United States
(12) Patent Application Publication
(10) Pub. No.: US 2006/0082296 A1
(43) Pub. Date: Apr. 20, 2006

(54) Mixture of alkaline earth metal thiogallate green phosphor and sulfide red phosphor for phosphor-converted LED

(76) Inventors: Janet Bee Yin Chua, Perak (MY); Hisham Menkara, Mableton, GA (US); Christopher J. Summers, Dunwoody, GA (US); Azlida Ahmad, Penang (MY); Hwai Peng Choo, Penang (MY)

Correspondence Address: AVAGO TECHNOLOGIES, LTD., P.O. BOX 1920, DENVER, CO, 80201-1920, US

(21) Appl. No.: 10/966,238

(22) Filed: Oct. 14, 2004

(51) Int. Cl. H01J 1/62; F21V 9/00; H01L 33/00

(52) U.S. Cl. 313/512; 362/293; 257/98

(57) ABSTRACT

A device and method for emitting output light of a desired color utilizes green-emitting Thiogallate phosphor material and red-emitting SrCaS:Eu phosphor material to convert some of the original light emitted from a light source of the device to a longer wavelength light in order to produce the desired output light. The green-emitting Thiogallate phosphor material includes at least one of CaGa₂S₄:Ce phosphor and BaGa₄S₇:Eu phosphor. The device and method can be used to produce white light or other mixed color light using the light source, which may be a blue-green light emitting diode (LED) die.

### BACKGROUND OF THE INVENTION

Conventional light sources, such as incandescent, halogen and fluorescent lamps, have not been significantly improved in the past twenty years. However, light emitting diode (“LEDs”) have been improved to a point with respect to operating efficiency where LEDs are now replacing the conventional light sources in traditional monochrome lighting applications, such as traffic signal lights and automotive taillights. This is due in part to the fact that LEDs have many advantages over conventional light sources. These advantages include longer operating life, lower power consumption, and smaller size.

LEDs are typically monochromatic semiconductor light sources, and are currently available in various colors from UV-blue to green, yellow and red. Due to the narrow-band emission characteristics, monochromatic LEDs cannot be directly used for “white” light applications. Rather, the output light of a monochromatic LED must be mixed with other light of one or more different wavelengths to produce white light. Two common approaches for producing white light using monochromatic LEDs include (1) packaging individual red, green and blue LEDs together so that light emitted from these LEDs are combined to produce white light and (2) introducing fluorescent material into a UV, blue or green LED so that some of the original light emitted by the semiconductor die of the LED is converted into longer wavelength light and combined with the original UV, blue or green light to produce white light.

Between these two approaches for producing white light using monochromatic LEDs, the second approach is generally preferred over the first approach. In contrast to the second approach, the first approach requires a more complex driving circuitry since the red, green and blue LEDs include semiconductor dies that have different operating voltages requirements. In addition to having different operating voltage requirements, the red, green and blue LEDs degrade differently over their operating lifetime, which makes color control over an extended period difficult using the first approach. Moreover, since only a single type of monochromatic LED is needed for the second approach, a more compact device can be made using the second approach that is simpler in construction and lower in manufacturing cost. Furthermore, the second approach may result in broader light emission, which would translate into white output light having higher color-rendering characteristics.

The second approach can also be used to produce mixed color light other than white light, such as light of different shades of green, by using different fluorescent material and/or using different LED die. Thus, the fluorescent material is a critical component in creating a phosphor-converted LED that produce light of a desired color. However, the fluorescent materials currently used to convert original UV, blue or green light results in phosphor-converted LEDs having less than desirable luminance efficiency, light output stability and/or desired color.

In view of this concern, there is a need for a device and method for emitting output light of desired color using one or more fluorescent phosphor materials with high luminance efficiency and good light output stability.

### SUMMARY OF THE INVENTION

A device and method for emitting output light of a desired color utilizes green-emitting Thiogallate phosphor material and red-emitting SrCaS:Eu phosphor material to convert some of the original light emitted from a light source of the device to a longer wavelength light in order to produce the desired output light. The green-emitting Thiogallate phosphor material includes at least one of CaGa₂S₄:Ce phosphor and BaGa₄S₇:Eu phosphor. The device and method can be used to produce white light or other mixed color light using the light source, which may be a blue-green light emitting diode (LED) die.

A device for emitting output light in accordance with an embodiment of the invention includes a light emitting diode die that emits first light of a first peak wavelength in a blue-green wavelength range and a wavelength-shifting region optically coupled to the light emitting diode to receive the first light. The wavelength-shifting region includes Thiogallate phosphor material having a property to convert some of the first light to second light of a second peak wavelength in the green wavelength range. The Thiogallate phosphor material includes at least one of CaGa₂S₄:Ce phosphor and BaGa₄S₇:Eu phosphor. The wavelength-shifting region further includes SrCaS:Eu phosphor material having a property to convert some of the first light to third light of a third peak wavelength in the red wavelength range. The first light, the second light and the third light are components of the output light.

A method for emitting output light in accordance with an embodiment of the invention includes generating first light of a first peak wavelength in a blue-green wavelength range, receiving the first light, including converting some of the first light to second light of a second peak wavelength in the green wavelength range using Thiogallate phosphor material and converting some of the first light to third light of a third peak wavelength in the red wavelength range using SrCaS:Eu phosphor material, and emitting the first light, the second light and the third light as components of the output light. The Thiogallate phosphor material includes at least one of CaGa₂S₄:Ce phosphor and BaGa₄S₇:Eu phosphor.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of a phosphor-converted LED in accordance with an embodiment of the invention.

FIGS. 2A, 2B and 2C are diagrams of phosphor-converted LEDs with alternative lamp configurations in accordance with an embodiment of the invention.

FIGS. 3A, 3B, 3C and 3D are diagrams of phosphor-converted LEDs with a leadframe having a reflector cup in accordance with an alternative embodiment of the invention.

FIG. 4 is a CIE chart showing different color emissions produced by phosphor-converted LEDs in accordance with an embodiment of the invention.

FIG. 5 shows the optical spectrums of phosphor-converted LEDs with BaGa₄S₇:Eu and SrCaS:Eu phosphor materials in accordance with an embodiment of the invention.

FIG. 6 is a plot of luminance (lv) degradation over time for a phosphor-converted LED with BaGa₄S₇:Eu and SrCaS:Eu phosphor materials in accordance with an embodiment of the invention.

FIG. 7 shows the optical spectrum of a phosphor-converted LED with CaGa₂S₄:Ce and SrCaS:Eu phosphor materials in accordance with an embodiment of the invention.

FIG. 8 is a plot of luminance (lv) degradation over time for a phosphor-converted LED with CaGa₂S₄:Ce and SrCaS:Eu phosphor materials in accordance with an embodiment of the invention.

FIG. 9 is a flow diagram of a method for emitting output light in accordance with an embodiment of the invention.

### DETAILED DESCRIPTION

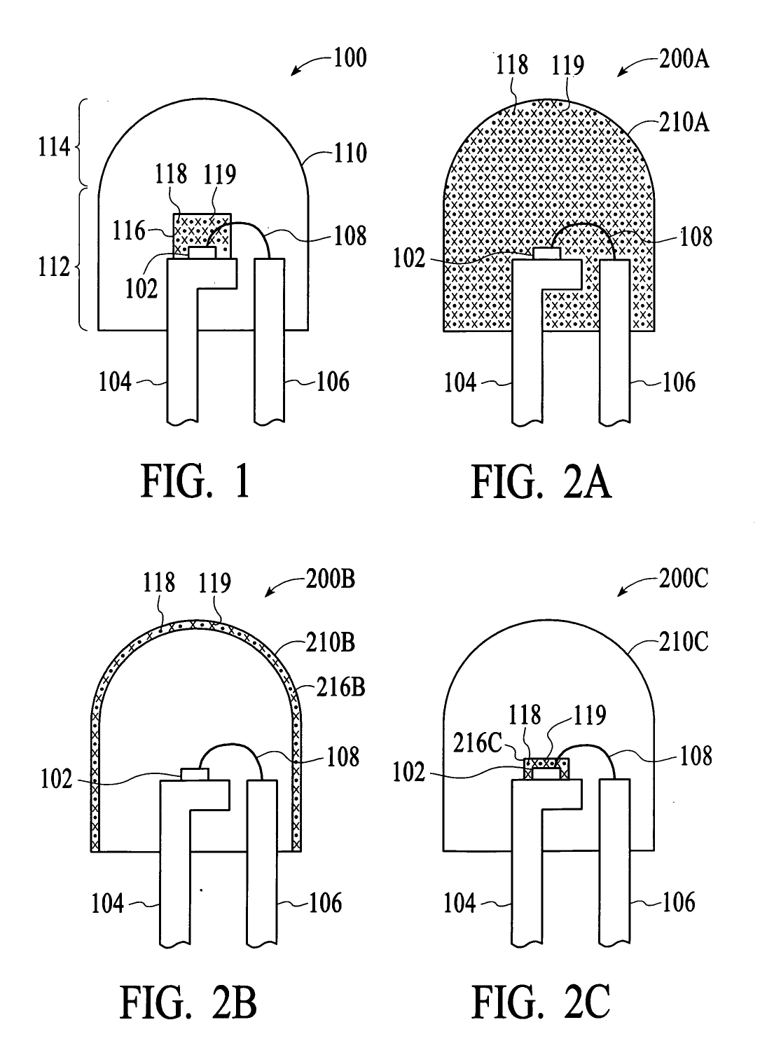

With reference to FIG. 1, a phosphor-converted light emitting diode (LED) 100 in accordance with an embodiment of the invention is shown. The LED 100 is designed to produce “white” or other mixed color output light with high luminance efficiency and good light output stability. The mixed color output light is produced by converting some of the original light generated by the LED 100 into longer wavelength light using Thiogallate phosphor material, which can convert some of the original light into green light, and SrCaS:Eu phosphor material, which can convert some of the original light into red light. The green-emitting Thiogallate phosphor material includes at least one of CaGa₂S₄:Ce phosphor and BaGa₄S₇:Eu phosphor.

As shown in FIG. 1, the phosphor-converted LED 100 is a leadframe-mounted LED. The LED 100 includes an LED die 102, leadframes 104 and 106, a wire 108 and a lamp 110. The LED die 102 is a semiconductor chip that generates light of a particular peak wavelength. Thus, the LED die 102 is a light source for the LED 100. In an exemplary embodiment, the LED die 102 is designed to generate light having a peak wavelength in a blue-green wavelength range of the visible spectrum, which is approximately 450 nm to 500 nm. The LED die 102 is situated on the leadframe 104 and is electrically connected to the other leadframe 106 via the wire 108. The leadframes 104 and 106 provide the electrical power needed to drive the LED die 102. The LED die 102 is encapsulated in the lamp 110, which is a medium for the propagation of light from the LED die 102. The lamp 110 includes a main section 112 and an output section 114. In this embodiment, the output section 114 of the lamp 110 is dome-shaped to function as a lens. Thus, the light emitted from the LED 100 as output light is focused by the dome-shaped output section 114 of the lamp 110. However, in other embodiments, the output section 114 of the lamp 100 may be horizontally planar.

The lamp 110 of the phosphor-converted LED 100 is made of a transparent substance, which can be any transparent material such as clear epoxy, so that light from the LED die 102 can travel through the lamp and be emitted out of the output section 114 of the lamp. In this embodiment, the lamp 10 includes a wavelength-shifting region 116, which is also a medium for propagating light, made of a mixture of the transparent substance and two types of fluorescent phosphor materials based on Thiogallate 118, which includes at least one of CaGa₂S₄:Ce and BaGa₄S₇:Eu, and SrCaS:Eu 119. The Thiogallate phosphor material 118 and the SrCaS:Eu phosphor material 119 are used to convert at least some of the original light emitted by the LED die 102 to lower energy (longer wavelength) light. The Thiogallate phosphor material 118 absorbs some of the original light of a first peak wavelength from the LED die 102, which excites the atoms of the Thiogallate phosphor material, and emits longer wavelength light of a second peak wavelength. In the exemplary embodiment, the Thiogallate phosphor material 118 has a property to convert some of the original light from the LED die 102 into light of a longer peak wavelength in the green wavelength range of the visible spectrum, which is approximately 520 nm to 540 nm. Similarly, the SrCaS:Eu phosphor material 119 absorbs some of the original light from the LED die 102, which excites the atoms of the SrCaS:Eu phosphor material, and emits longer wavelength light of a third peak wavelength. In the exemplary embodiment, the SrCaS:Eu phosphor material 119 has a property to convert some of the original light from the LED die 102 into light of a longer peak wavelength in the red wavelength range of the visible spectrum, which is approximately 625 nm to 740 nm. The second and third peak wavelengths of the converted light are partly defined by the peak wavelength of the original light and the Thiogallate phosphor material 118 and the SrCaS:Eu phosphor material 119. Any unabsorbed original light from the LED die 102 and the converted light are combined to produce mixed color light, which is emitted from the light output section 114 of the lamp 110 as output light of the LED 100.

The Thiogallate phosphor material 118 of CaGa₂S₄:Eu can be synthesized by various techniques. One technique involves using CaS and Ga₂S₃ as precursors. The precursors are ball-milled in a solution from the alcohol family, such as methanol, along with a small amount of Eu dopant, fluxes (Cl and F) and excess Sulfur. The amount of Eu dopant added to the solution can be anywhere between a minimal amount to approximately six percent of the total weight of all ingredients. The doped material is then dried and subsequently milled to produce fine particles. The milled particles are then loaded into a crucible, such as a quartz crucible, and sintered in a reduced and/or sulfur-rich atmosphere at around eight hundred degrees Celsius (800° C.) for one to two hours. The sintered materials can then be sieved, if necessary, to produce CaGa₂S₄:Eu phosphor powders with desired particle size distribution, which may be in the micron range.

The Thiogallate phosphor material 118 of BaGa₄S₇:Eu can also be synthesized by various techniques. One technique involves using BaS and Ga₂S₃ as precursors. The precursors are ball-milled in a solution from the alcohol family, such as methanol, along with a small amount of Eu dopant, fluxes (Cl and F) and excess Sulfur. The amount of Eu dopant added to the solution can be anywhere between a minimal amount to approximately six percent of the total weight of all ingredients. The doped material is then dried and subsequently milled to produce fine particles. The milled particles are then loaded into a crucible, such as a quartz crucible, and sintered in a reduced and/or sulfur-rich atmosphere at around eight hundred degrees Celsius (800° C.) for one to two hours. The sintered materials can then be sieved, if necessary, to produce BaGa₄S₇:Eu phosphor powders with desired particle size distribution, which may be in the micron range.

The SrCaS:Eu phosphor material 119 can also be synthesized by various techniques. One technique involves using SrS and CaS as precursors. The precursors are ball-milled in a solution from the alcohol family, such as methanol, along with a small amount of Eu dopant, fluxes (Cl and F) and excess Sulfur. The amount of Eu dopant added to the solution can be anywhere between a minimal amount to approximately six percent of the total weight of all ingredients. The doped material is then dried and subsequently milled to produce fine particles. The milled particles are then loaded into a crucible, such as a quartz crucible, and sintered in a reduced and/or sulfur-rich atmosphere at around one thousand degrees Celsius (1000° C.) for one to two hours. The sintered materials can then be sieved, if necessary, to produce SrCaS:Eu phosphor powders with desired particle size distribution, which may be in the micron range.

Each type of the above phosphor powders may be further processed to produce phosphor particles with a silica coating. Silica coating on phosphor particles reduces clustering or agglomeration of phosphor particles when the phosphor particles are mixed with a transparent substance to form a wavelength-shifting region in an LED, such as the wavelength-shifting region 116 of the lamp 110. Clustering or agglomeration of phosphor particles can result in an LED that produces output light having a non-uniform color distribution.

In order to apply a silica coating to phosphor particles, the sieved materials are subjected to an annealing process to anneal the phosphor particles and to remove contaminants. Next, the phosphor particles are mixed with silica powders, and then the mixture is heated in a furnace at approximately 200 degrees Celsius. The applied heat forms a thin silica coating on the phosphor particles. The amount of silica on the phosphor particles is approximately 1% with respect to the phosphor particles. The resulting phosphor particles with silica coating may have a particle size of less than or equal to thirty (30) microns.

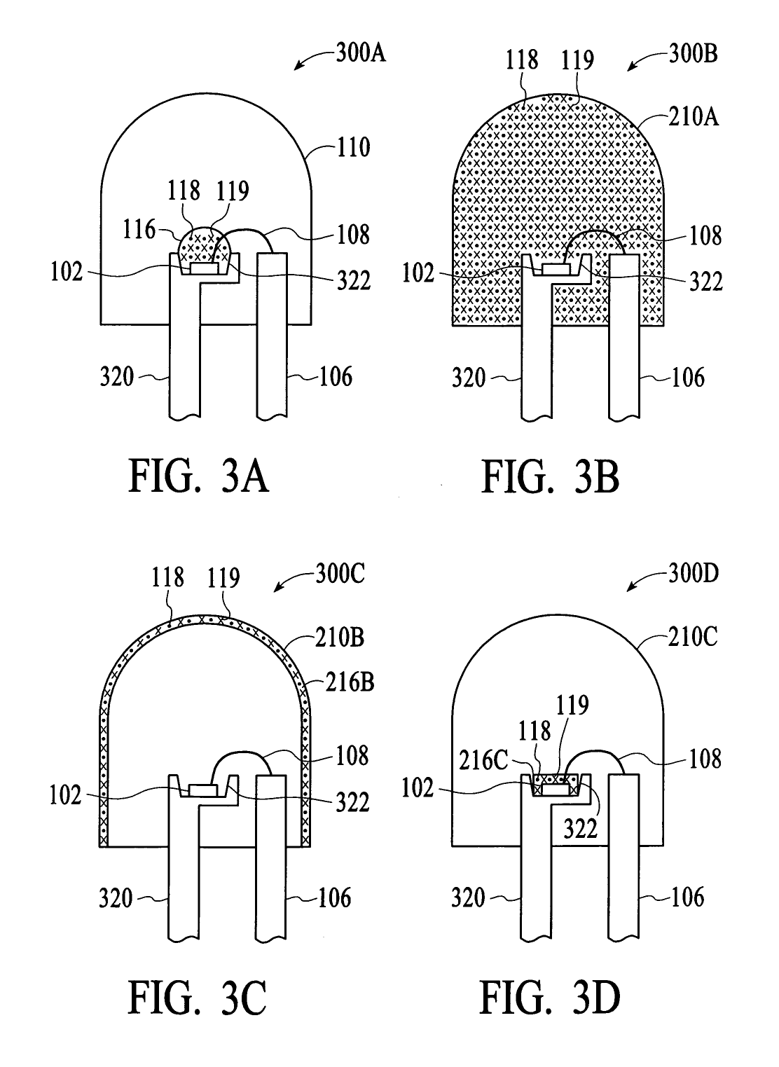

After the desired phosphor materials 118 and 119 are synthesized, the phosphor materials can be mixed with the same transparent substance of the lamp 110, e.g., epoxy, and deposited around the LED die 102 to form the wavelength-shifting region 116 of the lamp. The ratio between the two different types of phosphor materials can be adjusted to produce different color characteristics for the phosphor-converted LED 100. The remaining part of the lamp 110 can be formed by depositing the transparent substance without the phosphor materials 118 and 119 to produce the LED 100. Although the wavelength-shifting region 116 of the lamp 110 is shown in FIG. 1 as being rectangular in shape, the wavelength-shifting region may be configured in other shapes, such as a hemisphere, as shown in FIG. 3A. Furthermore, in other embodiments, the wavelength-shifting region 116 may not be physically coupled to the LED die 102. Thus, in these embodiments, the wavelength-shifting region 116 may be positioned elsewhere within the lamp 110.

In FIGS. 2A, 2B and 2C, phosphor-converted LEDs 200A, 200B and 200C with alternative lamp configurations in accordance with an embodiment of the invention are shown. The phosphor-converted LED 200A of FIG. 2A includes a lamp 210A in which the entire lamp is a wavelength-shifting region. Thus, in this configuration, the entire lamp 210A is made of the mixture of the transparent substance and the Thiogallate and SrCaS:Eu phosphor materials 118 and 119. The phosphor-converted LED 200B of FIG. 2B includes a lamp 210B in which a wavelength-shifting region 216B is located at the outer surface of the lamp. Thus, in this configuration, the region of the lamp 210B without the Thiogallate and SrCaS:Eu phosphor materials 118 and 119 is first formed over the LED die 102 and then the mixture of the transparent substance and the phosphor materials is deposited over this region to form the wavelength-shifting region 216B of the lamp. The phosphor-converted LED 200C of FIG. 2C includes a lamp 210C in which a wavelength-shifting region 216C is a thin layer of the mixture of the transparent substance and the Thiogallate and SrCaS:Eu phosphor materials 118 and 119 coated over the LED die 102. Thus, in this configuration, the LED die 102 is first coated or covered with the mixture of the transparent substance and the Thiogallate and SrCaS:Eu phosphor materials 118 and 119 to form the wavelength-shifting region 216C and then the remaining part of the lamp 210C can be formed by depositing the transparent substance without the phosphor materials over the wavelength-shifting region. As an example, the thickness of the wavelength-shifting region 216C of the LED 200C can be between ten (10) and sixty (60) microns, depending on the color of the light generated by the LED die 102 and the desired output light.

In an alternative embodiment, the leadframe of a phosphor-converted LED on which the LED die is positioned may include a reflector cup, as illustrated in FIGS. 3A, 3B, 3C and 3D. FIGS. 3A-3D show phosphor-converted LEDs 300A, 300B, 300C and 300D with different lamp configurations that include a leadframe 320 having a reflector cup 322. The reflector cup 322 provides a depressed region for the LED die 102 to be positioned so that some of the light generated by the LED die is reflected away from the leadframe 320 to be emitted from the respective LED as useful output light.

The different lamp configurations described above can be applied other types of LEDs, such as surface-mounted LEDs, to produce other types of phosphor-converted LEDs with Thiogallate and SrCaS:Eu phosphor materials 118 and 119 in accordance with the invention. In addition, these different lamp configurations may be applied to other types of light emitting devices, such as semiconductor lasing devices, to produce other types of light emitting device in accordance with the invention. In these light emitting devices, the light source can be any light source other than an LED die, such as a laser diode.

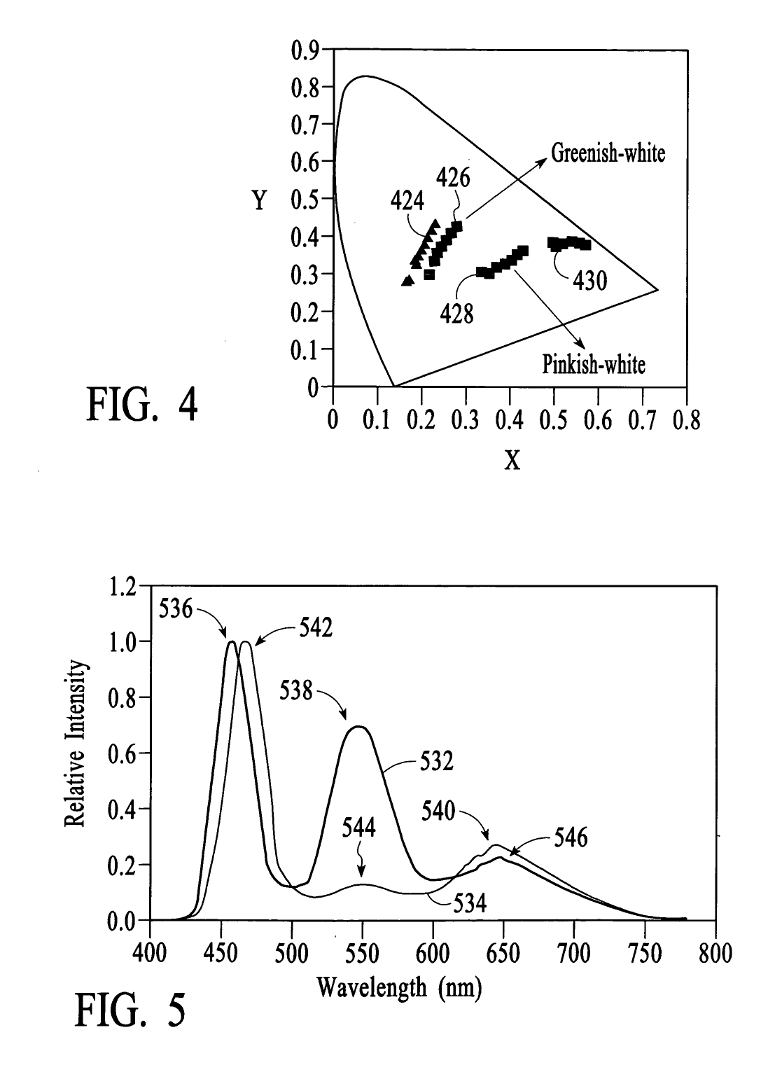

Turning now to FIG. 4, a Commission Internationale d'Eclairage (CIE) chart is shown. The CIE chart shows the color of output emissions 424, 426, 428 and 430 from four phosphor-converted LEDs in accordance with an embodiment of the invention. The output emissions 424 were produced using a phosphor-converted LED with fifty-five percent (55%) of CaGa₂S₄:Ce and SrCaS:Eu phosphor materials (9:1 ratio) relative to epoxy and a phosphor-converted LED die with excitation wavelength (peak wavelength) of 460 nm. The output emissions 426 were produced using a phosphor-converted LED with sixty-five percent (65%) of BaGa₄S₇:Eu and SrCaS:Eu phosphor materials (5:1 ratio) relative to epoxy and a phosphor-converted LED die with excitation wavelength of 460 nm. The output emissions 428 were produced using a phosphor-converted LED with sixty-five percent (65%) of BaGa₄S₇:Eu and SrCaS:Eu phosphor materials (7:3 ratio) relative to epoxy and a phosphor-converted LED die with excitation wavelength of 468 nm. The output emissions 430 were produced using a phosphor-converted LED with sixty-five percent (65%) of BaGa₄S₇:Eu and SrCaS:Eu phosphor materials (7:3 ratio) relative to epoxy and an LED die with excitation wavelength of 460 nm.

The CIE chart of FIG. 4 indicates that various mixed color light can be obtained by adjusting the ratio of green-emitting Thiogallate phosphor material to red-emitting SrCaS:Eu phosphor materials and/or using an LED die with different excitation wavelengths. As an example, the mixed color light of greenish color or reddish color can be obtained. Greenish color may include apple green lime green, aqua, sea green, grass green, peak green, etc. Reddish color may include light rose, hot pink, deep pink, crimson, mauve, burgundy, maroon, etc.

Turning now to FIG. 5, optical spectrums 532 and 534 of phosphor-converted LEDs in accordance with an embodiment of the invention is shown. The phosphor-converted LED associated with the optical spectrum 532 was made using sixty-five percent (65%) of BaGa₄S₇:Eu and SrCaS:Eu phosphor materials (5:1 ratio) relative to epoxy and an LED die with excitation wavelength of 460 nm. The phosphor-converted LED associated with the optical spectrum 534 was made using sixty-five percent (65%) of BaGa₄S₇:Eu and SrCaS:Eu phosphor materials (7:3 ratio) relative to epoxy and an LED die with excitation wavelength of 468 nm. The optical spectrum 532 includes a first peak wavelength 536 at around 460 nm, which corresponds to the excitation wavelength, a second peak wavelength 538 at around 545 nm, which is the peak wavelength of the light converted by the BaGa₄S₇:Eu phosphor material, and a third peak wavelength 540 at around 645 nm, which is the peak wavelength of the light converted by the SrCaS:Eu phosphor material. The resulting color of the optical spectrum 532 is greenish-white. Similarly, the optical spectrum 534 includes a first peak wavelength 542 at around 468 nm, which corresponds to the excitation wavelength, a second peak wavelength 544 at around 550 nm, which is the peak wavelength of the light converted by the BaGa₄S₇:Eu phosphor material, and a third peak wavelength 546 at around 645 nm, which is the peak wavelength of the light converted by the SrCaS:Eu phosphor material. The resulting color of the optical spectrum 534 is pinkish-white.

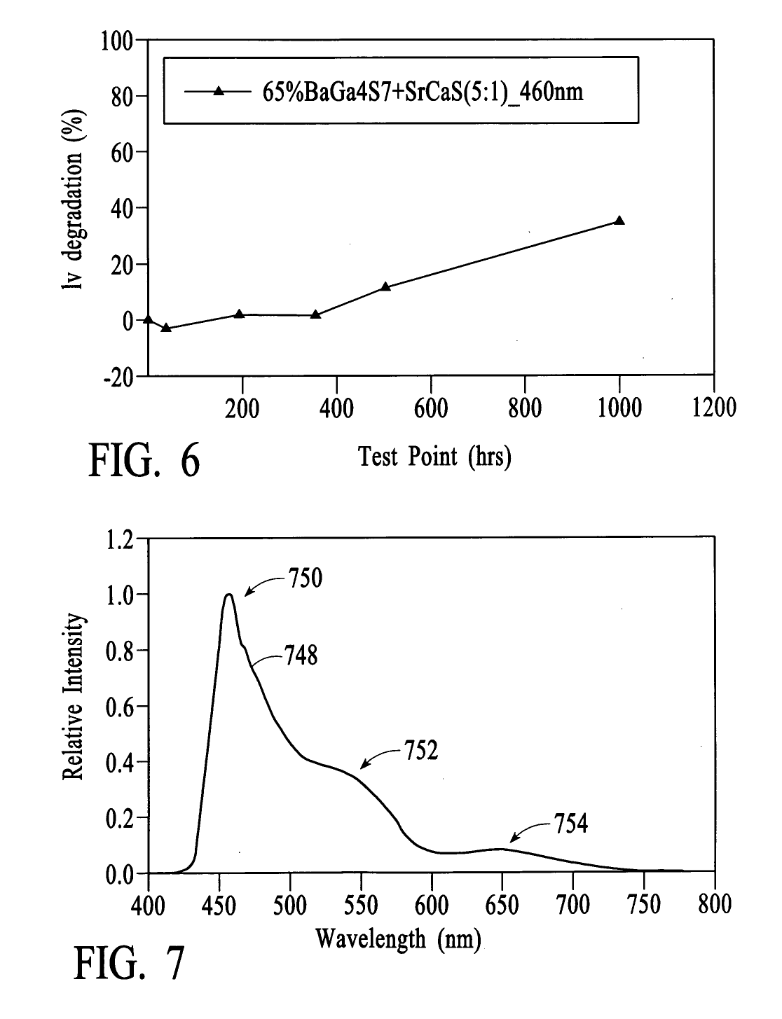

FIG. 6 is a plot of luminance (lv) degradation over time for a phosphor-converted LED made using sixty-five percent (65%) of BaGa₄S₇:Eu and SrCaS:Eu phosphor materials (5:1 ratio) relative to epoxy and an LED die with excitation wavelength of 460 nm in accordance with an embodiment of the invention. As illustrated by the plot of FIG. 6, the luminance properties of the phosphor-converted LED experience little change over an extended period of time while being exposed to high intensity light, i.e., the light emitted from the semiconductor die of the LED. Thus, the BaGa₄S₇:Eu and SrCaS:Eu phosphor materials used in the LED has good resistance against light. This resistance to light is not limited to the light emitted from the semiconductor die of an LED, but also any external light, such as sunlight including ultraviolet light. Thus, LEDs in accordance with the invention are suitable for outdoor use, and can provide stable luminance over time with minimal color shift.

Turning now to FIG. 7, an optical spectrum 748 of a phosphor-converted LED in accordance with an embodiment of the invention is shown. The phosphor-converted LED associated with the optical spectrum 748 was made using sixty-five percent (65%) of CaGa₂S₄:Ce and SrCaS:Eu phosphor materials (9:1 ratio) relative to epoxy and an LED die with excitation wavelength of 460 nm. The optical spectrum 748 includes a first peak wavelength 750 at around 460 nm, which corresponds to the excitation wavelength, a second peak wavelength 752 at around 535 nm, which is the peak wavelength of the light converted by the CaGa₂S₄:Ce phosphor material, and a third peak wavelength 754 at around 645 nm, which is the peak wavelength of the light converted by the SrCaS:Eu phosphor material.

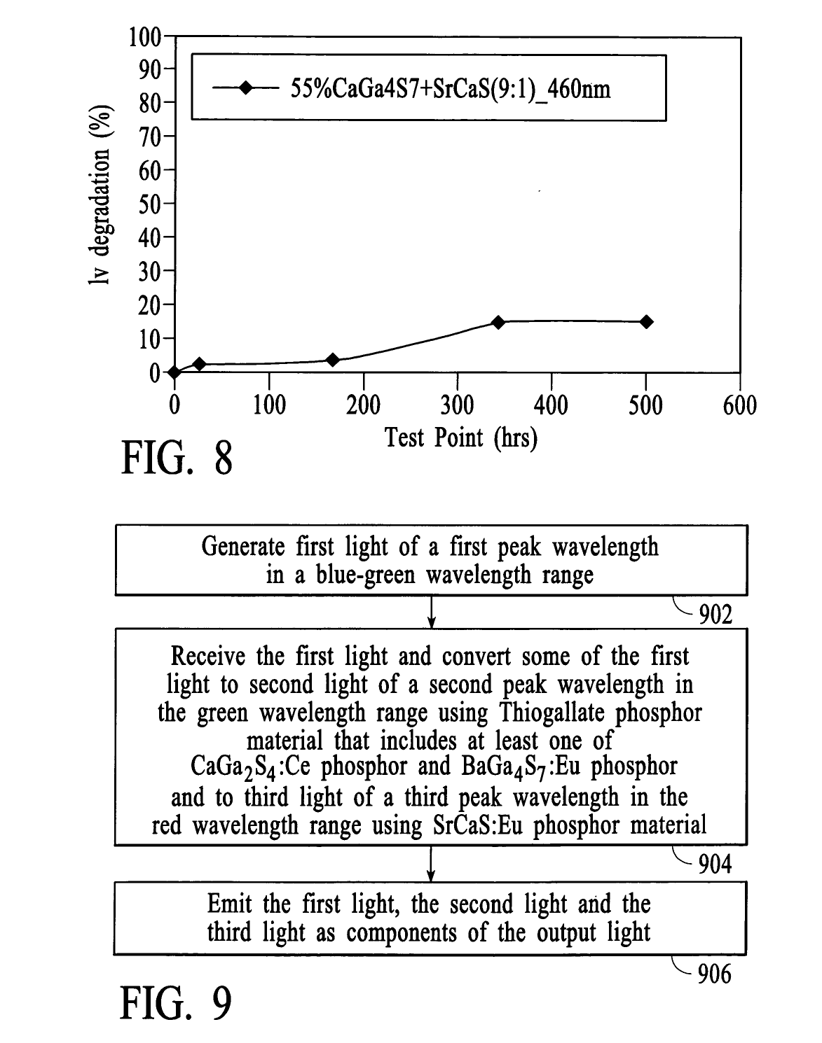

FIG. 8 is a plot of luminance (lv) degradation over time for a phosphor-converted LED made using sixty-five percent (65%) of CaGa₂S₄:Ce and SrCaS:Eu phosphor materials (9:1 ratio) relative to epoxy and an LED die with excitation wavelength of 460 nm in accordance with an embodiment of the invention. As illustrated by the plot of FIG. 8, the luminance properties of the phosphor-converted LED experience little change over an extended period of time while being exposed to high intensity light, i.e., the light emitted from the semiconductor die of the LED.

A method for producing output light in accordance with an embodiment of the invention is described with reference to FIG. 9. At block 902, first light of a first peak wavelength in a blue-green wavelength range is generated. The first light may be generated by an LED die. Next, at block 904, the first light is received and some of the first light is converted to second light of a second peak wavelength in the green wavelength range using Thiogallate phosphor material, which includes at least one of CaGa₂S₄:Ce phosphor and BaGa₄S₇:Eu phosphor. At block 904, some of the first light is also converted to third light of a third peak wavelength in the red wavelength range using SrCaS:Eu phosphor material. Next, at block 906, the first light, the second light and the third light are emitted as components of the output light.

Although specific embodiments of the invention have been described and illustrated, the invention is not to be limited to the specific forms or arrangements of parts so described and illustrated. The scope of the invention is to be defined by the claims appended hereto and their equivalents

What is claimed is:

1. A device for emitting output light, said device comprising:
a light emitting diode die that emits first light of a first peak wavelength in a blue-green wavelength range; and
a wavelength-shifting region optically coupled to said light emitting diode die to receive said first light, said wavelength-shifting region including Thiogallate phosphor material having a property to convert some of said first light to second light of a second peak wavelength in a green wavelength range, said Thiogallate phosphor material including at least one of CaGa₂S₄:Ce phosphor and BaGa₄S₇:Eu phosphor, said wavelength-shifting region further including SrCaS:Eu phosphor material having a property to convert some of said first light to third light of a third peak wavelength in a red wavelength range, said first light, said second light and said third light being components of said output light.

2. The device of claim 1 wherein said wavelength-shifting region is a part of a lamp coupled to said light emitting diode die.

3. The device of claim 2 wherein said wavelength-shifting region is located at an outer surface of said lamp.

4. The device of claim 1 wherein said wavelength-shifting region is a lamp coupled to said light emitting diode die.

5. The device of claim 1 wherein said wavelength-shifting region is a layer of mixture coated over said light emitting diode die, said mixture including said Thiogallate phosphor material and said SrCaS:Eu phosphor material.

6. The device of claim 1 further comprising a reflector cup on which said light emitting diode die is positioned.

7. The device of claim 1 wherein at least one of said Thiogallate phosphor material and said SrCaS:Eu phosphor material of said wavelength-shifting region includes phosphor particles.

8. The device of claim 7 wherein said phosphor particles of one of said Thiogallate phosphor material and said SrCaS:Eu phosphor material have a silica coating.

9. The device of claim 7 wherein said phosphor particles of one of said Thiogallate phosphor material and said SrCaS:Eu phosphor material have particle size of less than or equal to 30 microns.

10. A method for emitting output light from a light emitting diode, said method comprising:
generating first light of a first peak wavelength in a blue-green wavelength range;
receiving said first light, including converting some of said first light to second light of a second peak wavelength in a green wavelength range using Thiogallate phosphor material and converting some of said first light to third light of a third peak wavelength in a red wavelength range using SrCaS:Eu phosphor material, said Thiogallate phosphor material including at least one of CaGa₂S₄:Ce phosphor and BaGa₄S₇:Eu phosphor; and
emitting said first light, said second light and said third light as components of said output light.

11. The method of claim 10 wherein said receiving includes receiving said first light of said first peak wavelength at a wavelength-shifting region of said light emitting diode.

12. The method of claim 11 wherein said wavelength-shifting region is part of a lamp of said light emitting diode.

13. The method of claim 11 wherein said wavelength-shifting region is a lamp of said light emitting diode.

14. The method of claim 11 wherein said wavelength-shifting region is a layer of mixture coated over a light emitting diode die, said mixture including said Thiogallate phosphor material and said SrCaS:Eu phosphor material.

15. The method of claim 10 wherein at least one of said Thiogallate phosphor material and said SrCaS:Eu phosphor material includes phosphor particles.

16. The method of claim 15 wherein said phosphor particles of one of said Thiogallate phosphor material and said SrCaS:Eu phosphor material have a silica coating.

17. The method of claim 15 wherein said phosphor particles of one of said Thiogallate phosphor material and said SrCaS:Eu phosphor material have particle size of less than or equal to 30 microns.
